(19) United States
(12) Patent Application Publication
(10) Pub. No.: US 2006/0276043 A1
(43) Pub. Date: Dec. 7, 2006

(54) Method and systems for single- or multi-period edge definition lithography

(76) Inventors: Mark Alan Lamonte Johnson, Raleigh, NC (US); Douglas William Barlage, Durham, NC (US)

Correspondence Address: JENKINS, WILSON, TAYLOR & HUNT, P. A., 3100 TOWER BLVD, SUITE 1200, DURHAM, NC, 27707, US

(21) Appl. No.: 10/550,040

(22) PCT Filed: Mar. 22, 2004
(86) PCT No.: PCT/US04/08724

§ 371 Date: Jun. 28, 2006

Related U.S. Application Data
(60) Provisional application No. 60/456,775, filed on Mar. 21, 2003.
(60) Provisional application No. 60/456,770, filed on Mar. 21, 2003.

(51) Int. Cl. H01L 21/302

(52) U.S. Cl. 438/717

(57) ABSTRACT

Methods and systems for multiperiod, edge definition lithography are disclosed. According to one method, a first material is isotropically deposited on a substrate and on a field mesa also located on the substrate. The first masking material is then anisotropically removed from the substrate to leave a nanometer-pitched sidewall adjacent to the field mesa. A second masking material is then isotropically deposited on the substrate, the sidewall, and the field mesa. The second masking material is then anisotropically removed from the substrate to leave a second nanometer-pitched sidewall adjacent to the first sidewall. The process may be repeated to create alternating nanometer-pitched sidewalls of the first and second masking materials. One of the first and second masking materials may then be etched from the substrate to leave nanometer-pitched channels in one of the masking materials. The channels may be used to etch nanometer-pitched features in the substrate.

### RELATED APPLICATIONS

This application claims the benefit of U.S. Provisional Patent Application Ser. No. 60/456,775, filed Mar. 21, 2003, and U.S. Provisional Patent Application No. 60/456,770, file Mar. 21, 2003, the disclosures of each which are incorporated herein by reference in their entirety. This application relates to co-pending U.S. Patent Application entitled “METHODS FOR NANOSCALE STRUCTURES FROM OPTICAL LITHOGRAPHY AND SUBSEQUENT LATERAL GROWTH”, commonly owned and filed on even date herewith, the disclosure of which is incorporated herein by reference in its entirety.

### TECHNICAL FIELD

The present invention relates to methods and systems for improved edge definition lithography. More particularly, the present invention relates to methods and systems for making single- or multi-period, nanometer-pitched structures using edge definition lithography.

### BACKGROUND ART

In making semiconductor or electronic devices, it is often desirable to make features of increasingly small size in a semiconductor or other material. For example, in fabricating semiconductor devices, operational characteristics, such as frequency response related characteristics, vary inversely with the size of the patterned features that make up each device. Accordingly, semiconductor and nanoelectronic device fabrication focuses on different ways to make increasingly smaller device features.

One conventional semiconductor manufacturing technique used to make micrometer-pitched features is optical lithography or photolithography. In photolithography, a light-sensitive photoresist material is deposited on a substrate. A mask is placed over or in near contact to the photoresist material, and light is applied to expose portions of the photoresist material. The exposed portions of the photoresist material are then removed using a developer solution. Patterns may then be formed in the exposed portions of the substrate using chemical or plasma etching.

One problem with conventional photolithography is that the minimum feature size is limited by the wavelength of the light being used in the photolithographic processes. For example, some conventional optical lithographic processes are only capable of achieving feature sizes on the order of 0.5 micrometers, which is 500 nanometers. Such feature sizes are unsuitable for making nanoscale devices, such as nanoscale transistors. Due to this limitation of conventional photolithography, other lithographic patterning methods, such as x-ray lithography, deep ultraviolet lithography, electron beam lithography, and phase shift lithography have been developed. However, these processes are typically one to two orders of magnitude more expensive than photolithographic techniques due to expense and complexity of the lithography instruments and related masks or chemicals. In addition, these processes typically require specialized equipment with low throughput, making them unsuitable for fabricating quantities of nanoscale devices.

One method for fabricating submicron-scale devices using photolithography is edge definition or spacer gate lithography. In edge definition or spacer gate lithography, a masking material is deposited adjacent to an edge of a mesa or raised portion on a semiconductor substrate. After the initial deposition, the mesa is etched from the substrate, leaving a submicron-pitched line of the masking material on the substrate. The submicron-pitched line may be used as a mask for etching the underlying substrate. After forming the submicron-pitched line or etching the underlying substrate, the masking material may be removed or left, depending on the device being fabricated and the masking material used. Such edge definition lithography has been used to create single line features, such as a submicron-scale gate for a GaAs MESFET.

Another photolithographic technique used to create single-line, submicron-scale features in an underlying material is shadow masking. In shadow masking, two layers of resist material are deposited on a substrate. Photolithography is used to create a plug in the uppermost resist material. The plug casts a shadow on the lowermost material that resists subsequent angle evaporation of the lowermost resist material. The resist material left by the shadow may then be used to define a submicron line feature on the underlying substrate. In shadow masking, the linear dimension of the submicron feature is controlled by the vertical dimension of the photoresist material and the angle of the subsequent evaporation. The minimum nanoscale feature size controllably achievable by shadow masking technique is controlled by the ability to control the thickness and sharpness of the photoresist plug as well as the angular variation of the evaporation shadow umbra and penumbra.

While edge definition lithography and shadow masking are suitable for creating submicron-scale features, neither technique has been extended to produce periodic arrays of nanoscale features required for nanoscale devices. Accordingly, there exists a long-felt need for improved methods and systems for edge definition lithography that are suitable for producing single or multiperiodic nanoscale features. Furthermore, there is the opportunity to utilize edge definition lithography for the formation of nanoscale devices using new materials and new devices for which this process has not been applied.

### DISCLOSURE OF THE INVENTION

According to one aspect, the present invention includes improved methods and systems for spacer gate or edge definition lithography that enable the production of periodic arrays of nanoscale features. In one method, a field mesa is defined on a substrate using conventional photolithographic techniques or other lithographic methods. Next, a first masking material is deposited on the substrate and on both the top and side of the mesa. The deposition is preferably performed isotropically or with a controlled amount of anisotropy.

In the next step, the first masking material is anisotropically removed from the substrate to leave a nanometer-scale sidewall adjacent to the mesa. The anisotropic removal should preferentially remove the masking material from the top of the mesa relative to the side of the mesa.

Next, a second masking material is deposited with a limited degree of deposited on the substrate, the first sidewall, and the field mesa. The second masking material is then anisotropically removed from the substrate to leave a second nanometer-scale sidewall adjacent to the first nanometer-scale sidewall. The process is repeated to produce an alternating pattern of nanometer-scale sidewalls of the first and second masking materials.

In the next step, the mesa and one of the masking materials are preferentially etched from the substrate to leave sidewalls of the other masking material on the substrate separated by nanoscale channels in the remaining masking material. Etching of the mesa and sidewall may be a single or two etch steps. The resulting structure is a periodic array of masking materials with parallel nanometer scale dimensions. Nanoscale channels may then be etched in the substrate via the exposed channels in the remaining masking material. The masking material may then be left on or removed from the substrate, depending on the desired application.

In this manner, multiperiod, nanometer-pitched features can be formed in a substrate using photolithography. As a result, nanoscale device features can be achieved using lithographic equipment that is orders of magnitude less expensive that that used for advanced lithographic techniques, such as electron beam lithography. As used herein, the terms “nanoscale”, “nanometer-pitched”, and “nanometer-dimensioned” are used to describe features that are have nanometer-scale dimensions, such as dimensions on the order of about 2 nanometers to about 100 nanometers and more particularly on the order of about 10 nanometers to about 50 nanometers. Accordingly, it is an object of the invention to provide methods and systems for forming multiperiodic, nanometer-pitched, features in a substrate using photolithography.

It is another object of the invention to provide nanometer-pitched devices or structures made using multiperiod edge definition optical lithography.

Some of the objects of the invention having been stated hereinabove, and which are addressed in whole or in part by the present invention, other objects will become evident as the description proceeds when taken in connection with the accompanying drawings as best described hereinbelow.

### BRIEF DESCRIPTION OF THE DRAWINGS

Preferred embodiments of the invention will now be explained with reference to the accompanying drawings of which:

FIGS. 1A-1I are side views of a substrate illustrating multiperiod edge definition lithography according to an embodiment of the present invention;

FIGS. 2A and 2B are a top views illustrating exemplary two- and three-dimensional arrays made using multiperiod edge definition lithography according to an embodiment of the present invention;

FIGS. 2C and 2D are sectional views taken through lines C-C′ and D-D′ illustrated in FIG. 2B;

FIGS. 3A-3D are side views illustrating in more detail exemplary deposition and etching techniques used in multiperiod edge definition lithography according to an embodiment of the present invention;

FIGS. 4A-4E are side views of a substrate illustrating the formation of a nanometer-scale feature using edge definition lithography and lift off removal according to an embodiment of the present invention; FIGS. 5A and 5C are side views of a substrate illustrating formation of an electronic device using the nanometer-pitched feature created in FIG. 4D or 4E

FIGS. 6A-6D are side views of a compound semiconductor substrate with positive nanoscale features made using edge definition lithography according to an embodiment of the present invention;

FIGS. 7A-7D are side views of a compound semiconductor substrate with negative nanoscale features made using edge definition lithography according to an embodiment of the present invention;

FIG. 8A is a side view of a positive nanometer-pitched feature formed in a micrometer-pitched channel using edge definition lithography according to an embodiment of the present invention;

FIG. 8B is a side view of a positive nanometer-pitched feature formed in a micrometer-pitched channel using edge definition lithography according to an embodiment of the present invention;

FIG. 8C is a side view of a negative nanometer-pitched feature formed in a micrometer-scale channel according to an embodiment of the present invention;

FIG. 8D is a side view of a negative nanometer-pitched feature formed on a micrometer-scale mesa according to an embodiment of the present invention;

FIG. 9A-9D are side views of a nanometer-pitched HFETs or MESFETs formed using edge definition lithography according to an embodiment of the present invention; and

FIG. 10A is a side view of a heterojunction biopolar junction transistor formed using edge definition lithography according to an embodiment of the present invention;

FIG. 10B is a side view of a heterojunction bipolar junction transistor formed using edge definition lithography according to an embodiment of the present invention; and

FIG. 10C is a perspective view of a heterojunction bipolar junction transistor formed using edge definition lithography according to an embodiment of the present invention.

### DETAILED DESCRIPTION OF THE INVENTION

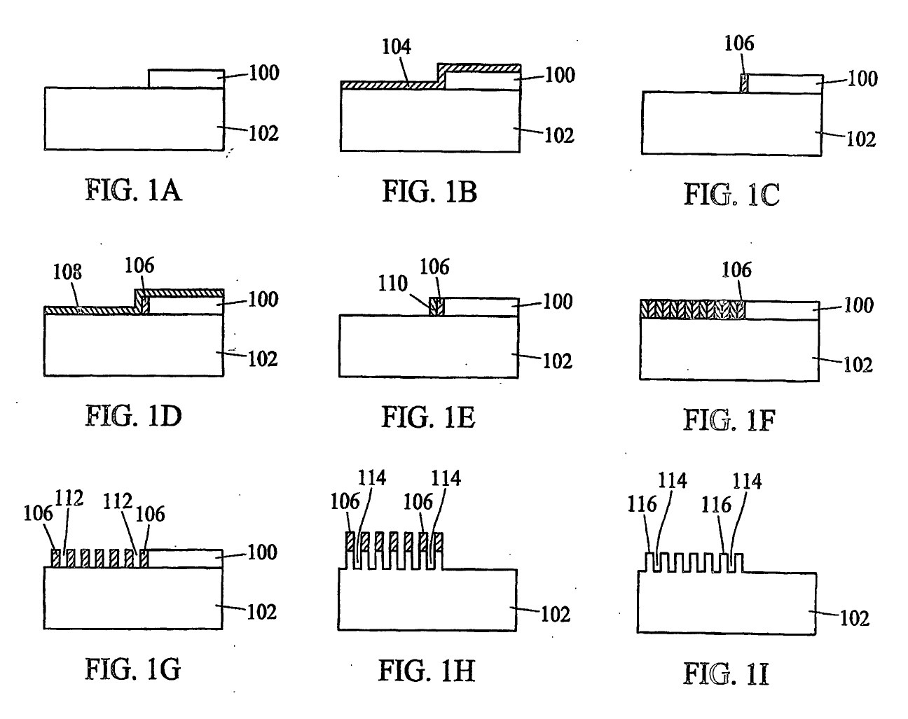

As stated above, the present invention includes methods and systems for multiperiod edge definition lithography. FIGS. 1A through 1I illustrate an exemplary multiperiod edge definition lithography method according to an embodiment of the present invention. Referring to FIG. 1A, a block feature or mesa 100 is defined on a substrate 102 using standard photolithographic techniques. The spatial dimensions of mesa 100 may be consistent with the diffraction-limited focusing conditions of standard or advanced lithographic fabrication techniques. For example, mesa 100 may be 1 micrometer in linear dimension. The thickness of mesa 100 may be selected according to the desired height of nanometer-scale lines to be formed on substrate 102. Mesa 100 may consist of a photoresist, a metal, or an insulator. One feature of mesa 100 is that it preferably has an etch chemistry that will allow differential removal of feature 100 after fabrication of masking material arrays, while it must be chemically robust to withstand the deposition and etching process used during edge defined lithography. Substrate 102 may be a single-element semiconductor material, such as silicon, or a compound semiconductor material, such as gallium nitride, gallium arsenide, indium gallium arsenide, indium phosphide, silicon carbide, or related ternary or related quaternary semiconductor alloys. Furthermore, substrate 102 may be a homogeneous semiconductor material or contain multiple layer heterostructure combinations of materials.

In FIG. 1B, a first masking material 104 is deposited isotropically or with a controlled degree of anisotropy on substrate 102 and mesa 100 such that masking material 104 covers substrate 102 and mesa 100. The degree of anisotropy of deposition of material 104 can be controlled using in-situ process controls, such as optical measurements, quartz crystal monitoring, or quadrupole mass spectrometry, etc. Alternatively, the deposition of masking material 104 can be measured using ex-situ process measurements such as profilometry, optical measurements, or scanning microscopy. The deposition of material 104 may be isotropic or have a degree of anisotropy as measured by the thickness of material 104 on perpendicular to and side surfaces of mesa 100. Masking material 104 preferably has a different etch chemistry relative to mesa 100 and to a second masking material that will subsequently be deposited on the substrate. Another criteria for selecting a suitable masking material 104 is that the material selected for use as masking material 104 be capable of persisting as a residual component where needed as component of a subsequently fabricated device. For example, if the device is a transistor, masking material 104 is preferably selected to be a suitable gate material for the transistor. Alternatively, in applications where it is only desired to form nanometer-pitched features in substrate 102, masking material need not be selected to have operational properties suitable for use in the nanometer-pitched electronic, optical, mechanical, or electromechanical device.

Referring to FIG. 1C, in the next step of the process, masking material 104 is anisotropically etched from substrate 102 and from mesa 100, leaving a nanometer-pitched sidewall 106 adjacent to mesa 100. In order to produce sidewall 106, there must be a difference in anisotropy of the deposition and removal processes. For example, if the deposition of material 104 is nearly isotropic, the removal must have a greater degree of anisotropy to leave sidewall 106. Alternatively, the deposition may be anisotropic, preferentially depositing more material in the area of sidewall 106, and the removal may be isotropic, still leaving sidewall 106.

Once mesa 100 and masking material 104 have been removed from substrate 102, the remaining structure is sidewall 106. In conventional edge defined lithography, after preferential removal of mesa 100, sidewall 106 was used as a mask or a feature in a subsequent device. This process has been previously demonstrated using only silicon or GaAs as the substrate. In the present invention, substrate 102 may be a compound semiconductor material, such as GaN, AlGaN, InGaN, or any related material. Furthermore, it may be desirable to fabricate an edge-defined feature 106 where the underlying substrate 102 consists of a semiconductor heterostructure containing silicon, GaAs, InGaAs, AlGaAs, SiGe, SiC, GaN, AlGaN, InGaN, or any related semiconductor compounds as two or more distinct types of controlled dimension. In addition, the processes described herein enable periodic arrays of nanometer-pitched features to be formed by depositing and removing materials from substrate 102. Referring to FIG. 1D, a second masking material 108 is deposited on substrate 102, mesa 100, and sidewall 106. As with the deposition of the first sidewall, the deposition of material 108 may be performed isotropically or with a predictable and limited degree of anisotropy. Material 108 is preferably selected to have a differential and controllable etch chemistry with regard to that of mesa 100 and masking material 104. Material 108 may also be selected to have operational properties consistent with an end device. For example, if the end device is a transistor, material 108 may be chosen to have electrical conductivity or dielectric properties suitable for use as a gate material. Examples of materials suitable for use as masking materials 104 and 108 include conductive materials, insulating materials, or any of the single-element or compound semiconductor materials described above with regard to substrate 102, provided that the differential etch chemistry requirements are met. Furthermore, materials 104 and 108 may be semiconductor or non-semiconductor dielectric materials, which are crystalline, polycrystaline, or non-crystaline. Examples of semiconductor or non-semiconductor materials include silicon nitride, silicon oxide, and silicon nitride or silicon oxide containing compounds.

Referring to FIG. 1E, in the next step, material 108 is anisotropically etched from substrate 102, mesa 100, and sidewall 106, to form a second sidewall 110 adjacent to sidewall 106. The etching of material 108 is preferably performed with a degree anisotropy that is different from the deposition. That is, if the deposition is nearly isotropic, the etching is preferably anisotropic so that there is a greater effective cross section for material removal in the area of sidewall 110. The result of the anisotropic etch is a patterned feature with a lateral dimension comparable to the thickness of isotropically deposited material 108. Furthermore, the anisotropic etching of material 108 to form feature 110 should have only limited etching effect on either the original feature 106 or mesa 100.

Referring to FIG. 1F, the process described with regard to FIGS. 1B-1E is repeated to form a periodic array of sidewalls 106 and 110 formed alternatingly of materials 104 and 108. Each sidewall may comprise a line on substrate 102 having a thickness ranging from about 1 nanometer to about 100 nanometers. The linear dimensions of alternating layers 106 and 110 may be consistent upon repeated multiple depositions or may vary upon subsequent multiple depositions based on the requirements of the nanoscale device. The linear dimension of each subsequent layer is controlled by the thickness of the subsequent deposition of materials 104 and 108.

Referring to FIG. 1G, one of materials 104 and 108 may be selectively etched from the substrate. In the example illustrated in FIG. 1G, sidewalls 110 of material 108 have been removed from the substrate to leave sidewalls 106 of material 104. Each sidewall 106 is spaced by a nanometer-pitched channel 112. In an alternate example, sidewalls 106 may be etched from substrate 102 leaving sidewalls 110 and nanometer-spaced channels between sidewalls 110. Depending on the requirements of the specific nanoscale device, the resulting structure may be sufficient for nanoscale device fabrication.

Referring to FIG. 1H, in the next step of one exemplary process, substrate 102 is anisotropically etched between sidewalls 106 to form channels 114. Each channel 114 may have a width that is on the order of 1 to 100 nanometers. In addition, field mesa 100 is also removed from substrate 102. Depending on the requirements of the specific nanoscale device, the resulting structure may be sufficient for nanoscale device fabrication.

Referring to FIG. 1I, in the next step of the process, sidewalls 106 are etched from substrate 102. Thus, substrate 102 has multiperiodic, nanospaced features 116 suitable for large scale integration of nanometer-pitched devices. In an alternate process, sidewalls 106 may remain on substrate 102 and may themselves be used as features for creating nanoscale devices.

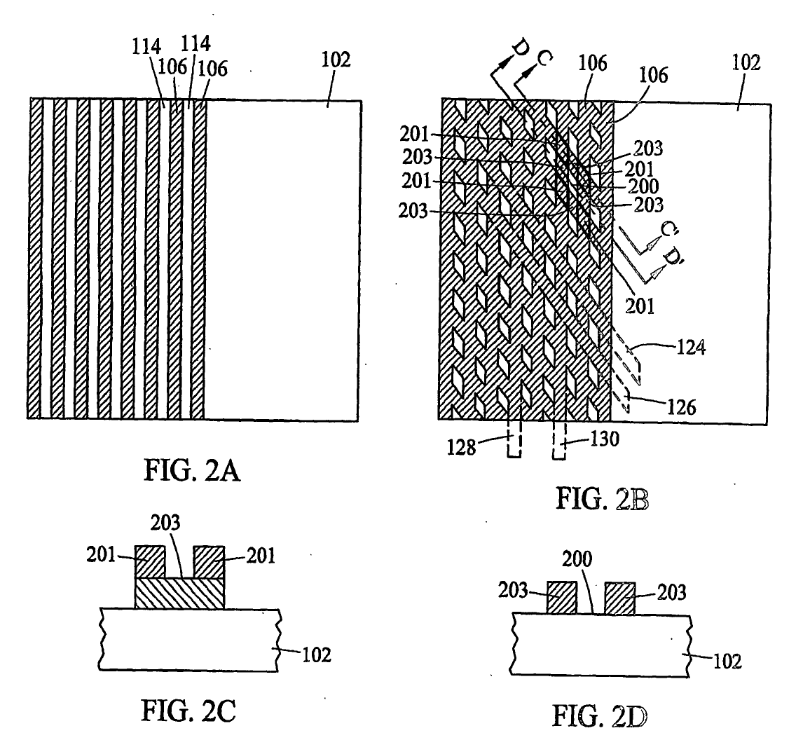

FIGS. 2A and 2B are top views of substrate 102 illustrating multiperiod nanoscale features created using the process described above with regard to FIGS. 1A-1I. Referring to FIG. 2A, substrate 102 includes a one-dimensionally array of nanometer-spaced sidewalls separated by nanometer-spaced channels 114. The top view illustrated in 2A may correspond to the side view illustrated in FIGS. 1G, 1H, or 1I.

FIG. 2B illustrates a two-dimensional array of nanometer-spaced features. In FIG. 2B, nanometer-spaced sidewalls 106 are formed in two directions on substrate 102. More particularly, sidewalls 106 extend in a first direction where the sidewalls are parallel to each other and in a second direction that is at an oblique angle to the first direction. The intersection of sidewalls 106 forms nanometer-pitched holes 200. The array of sidewalls 106 extending in one direction is represented by extensions 124 and 126. The array of sidewalls 106 extending in the second direction is represented by extensions 128 and 130.

The arrays of sidewalls in the first direction may be formed on top of the array extending in the second direction. For example, The resulting structure may result in nanometer pitched pillars or material in a three-dimensional array including double-height pillars 201, single-height pillars 203, and zero-height holes 200. FIGS. 2C and 2D are sectional views that illustrate the relative heights of features 200, 201, and 203 in more detail.

The pitch, spacing, or shape of the nanometer-scaled features in a two-dimensional array may be determined by an angle θ 202 of relationship between the first and second sets of linear nanoscale features fabricated using edge definition lithography. The angle θ 202 between the first and second arrays of edge defined features may vary between 0 and 180 degrees and may form an oblique or perpendicular angle between layers.

Two or more subsequent linear arrays may be combined to form a two-dimensional array of nanoscale features of increasing complexity or a three-dimensional array of nanoscale features. The resulting two- or three-dimensional array may be used either directly as a nanoscale device or as a template for further fabrication of a nanoscale device.

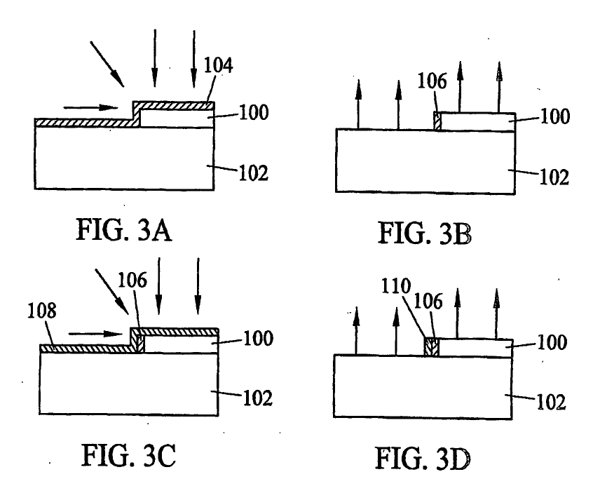

FIGS. 3A though 3D illustrate exemplary deposition and removal processes according to the invention in more detail. More particularly, referring to FIG. 3A, material 104 is isotropically deposited on substrate 102 and field mesa 100. The arrows illustrated in FIG. 3A indicate that deposition of material 104 is preferable equal in all directions, including deposition in the direction near the edge of field mesa 100. The cross-sectional area of material 104 is thicker when viewed from a plane perpendicular to the surface of substrate 102 in the area adjacent to the sidewall of mesa 100 than the cross-sectional areas of material 104 on mesa 100 or in other areas on substrate 102. However, the cross-sectional area of material 104 is preferably uniform when viewed from a direction that is always perpendicular to its underlying surface. That is, the cross-sectional area of material 104 along the surface of substrate 102 is equal to the cross-sectional area of material 104 when traveling up the edge of mesa 100. Both of these cross-sectional areas are also equal to the cross-sectional area of material 104 when traveling across the surface of mesa 100.

In FIG. 3B, material 104 is anisotropically removed from field mesa 100 and substrate 104 to form sidewall 106. That is, using conventional etching techniques, material 104 occur in a preferential manner such that etching of material 104 occurs at a greater rate in the vertical direction but not in the lateral direction. As a result, because the material adjacent to field mesa 100 is thicker in the vertical direction, sidewall 106 will remain on substrate 102. The arrows illustrated in FIG. 3B correspond to anisotropic removal in the vertical direction, but not in the lateral direction.

Referring to FIG. 3C, material 108 is isotropically deposited on substrate 102, field mesa 100 and sidewall 106. The arrows illustrated in FIG. 3C indicate that the thickness of material 108 has a uniform cross section when viewed from a plane perpendicular to its underlying surface. That is, the cross-sectional area of material 108 is preferably uniform when viewed along the surface of substrate 102 from a plane perpendicular to surface 102 until the area adjacent to sidewall 106 is reached. Once sidewall 106 is reached, the underlying surface becomes the edge of sidewall 106 and the cross-sectional area of material 108 when traveling across substrate 102. The cross-sectional area of material 108 on top of mesa 100 is equal to the cross-sectional area of material 108 when traveling across substrate 102 and across the edge of sidewall 106. However, when viewed from a direction that is always perpendicular to the surface of substrate 102, the cross-sectional area of material 108 is thicker in the region adjacent to sidewall 106. This thicker cross-sectional area allows material 108 to be anisotropically removed from substrate 102 and mesa 100 without removing sidewall 110.

Referring to FIG. 3D, material 108 is anisotropically etched from substrate 102, field mesa 100, and sidewall 106. For example, conventional etching techniques, such as plasma etching, may be used such that the etching of material 108 is preferably uniform in the direction perpendicular to the surface of substrate 102 but not in the direction parallel to the surface of substrate 102. Because material 108 is thicker adjacent to sidewall 106, sidewall 110 remains on substrate 102 after the etching. Thus, using the steps illustrated in FIGS. 3A through 3D, alternating, nanometer-pitched sidewalls may be formed on the substrate using conventional photolithographic techniques and a combination of isotropic deposition and anisotropic etching of overlayer materials. Conventional deposition techniques, such as chemical vapor deposition or thermal deposition may be used under process conditions such that an isotropically deposited layer is obtained. Alternatively, another material deposition process may be used such that the deposited layer is isotropic, resulting in a thickness of material 104 or 108 that is greater in the area adjacent to the feature edge (100, 106, or 110) when viewed perpendicularly from substrate 102.

Conventional etching techniques, such as plasma etching, chemical etching, or photo-assisted chemical etching may be used for anisotropic etching of the edge defined features 106 or 110. Alternatively, another material etching process may be used provided the rate of etching is greater in the director perpendicular to the surface of substrate 102 than in the direction parallel to the surface of substrate 102.

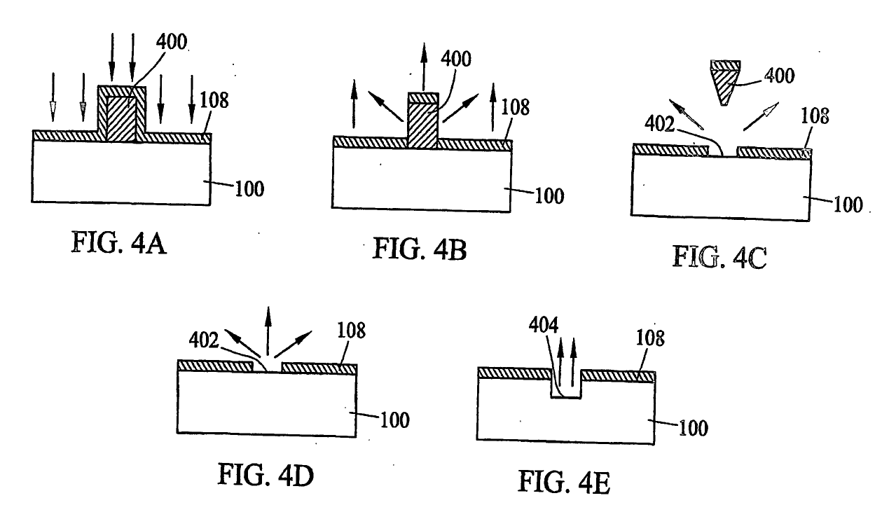

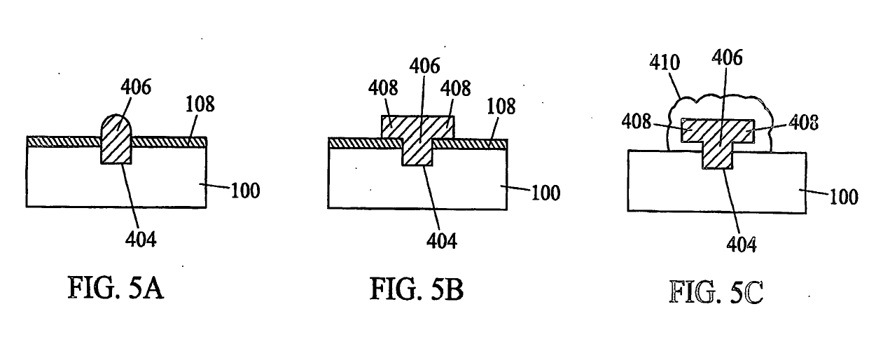

FIGS. 4A through 4D illustrate another application of edge definition lithography to create nanometer-pitched features according to an embodiment of the present invention. Referring to FIG. 4A, second masking material 108 is deposited on substrate 102 and nanometer-pitched sidewall 400. Nanometer-pitched sidewall 400 may be formed using edge definition lithography, as described above, or any other nanometer scale lithographic process. The deposition of masking material 108 on sidewall 400 and substrate 102 is preferably anisotropic. That is, deposition may be uniform in the vertical direction and non-uniform in the lateral direction on one or more of the opposing sides of sidewall 400 to form at least one thin sidewall on opposite sides of sidewall 400.

In FIG. 4B, masking material 108 is isotropically etched from substrate 102 and from sidewall 400. The etching is preferably performed such that the thin sidewalls formed of masking material 108 are removed from the sides of sidewall 400, while leaving material 108 on the top surface of nanoscale feature 400 or the surface of substrate 100. In FIG. 4C, sidewall 400 is removed from substrate 400 using a lift-off process to leave a nanometer-pitched channel 402 in second masking material 108. In FIG. 4D, any material remaining from sidewall 400 in channel 402 is preferentially etched from channel 402 to expose substrate 102. Depending upon the desired nanoscale device, the feature illustrated in FIG. 4D may be sufficient for the fabrication of a structure of nanoscale dimensions. The structure so defined yields a nanoscale channel for which the feature is defined essentially parallel with the substrate surface. Alternatively, for some devices, the nanoscale feature may be recessed into the subsequent substrate surface. In FIG. 4E, substrate 102 is anisotropically etched using masking material 108 as a nanometer scale pattern template. The result is a nanometer-pitched channel 404 recessed into substrate 102.

FIGS. 5A-5C illustrate an extension of the process illustrated in FIGS. 4A through 4E. Referring to FIG. 5A, channel 404 is filled with a material 406. Material 406 may be a conductive material suitable for use as a gate material in a transistor or nanoscale device. In FIG. 5B, sidewalls 408 are deposited on opposing sides of material 406 to form a mushroom-shaped structure. Sidewalls 408 may be of the same material as material 406. The sidewall formation on mushroom structure 406 may be performed using a nanoscale or microscale lithographic process. In FIG. 5C, material 108 is etched from the substrate and the mushroom shaped structure formed by sidewalls 406 and 408 is encapsulated in an encapsulating material 410. Encapsulating material 410 may be a dielectric, such as silicon nitride, silicon oxide, or a compound containing an oxide or nitride dielectric. The purpose of material 410 is to isolate or insulate material 406 from subsequent fabrication processes. Additionally, material 410 may provide functionality for the subsequently fabricated nanoscale device, such as a dielectric influencing the electric fields surrounding the nanoscale feature 406. The material 410 may be chemically identically or chemically different that the material of substrate 102 or edge defined material 108.

Nanoscale feature 406 may be recessed in substrate 100 or parallel to substrate 100, depending on whether the nanoscale feature is etched in the earlier process described about with respect to FIG. 4. If the feature is parallel to the surface of substrate 102, the process defined in FIGS. 5A-5C may occur on the nanoscale feature shown in FIG. 4D.

Thus, using the steps illustrated in FIGS. 4A through 5C, complex, nanometer-pitched features can be created using edge-definition lithography.

The processes described above may be used to form a variety of nanometer-pitched electronic and nano-electro mechanical devices. Examples of devices that may be formed using the above described techniques include heterostructure field effect transistors (FETS), heterojunction bipolar junction transistors (BJTs), gallium nitride and indium gallium nitride based FETs, gallium arsenide and indium gallium arsenide based FETs, and indium phosphide based FETs. Such BJTs or FETs may be comprised of an underlying semiconductor layer which is homogeneous in composition or heterogeneous in composition as heterojunction FETs (HFETs), or heterojunction BJTs (HBTs).

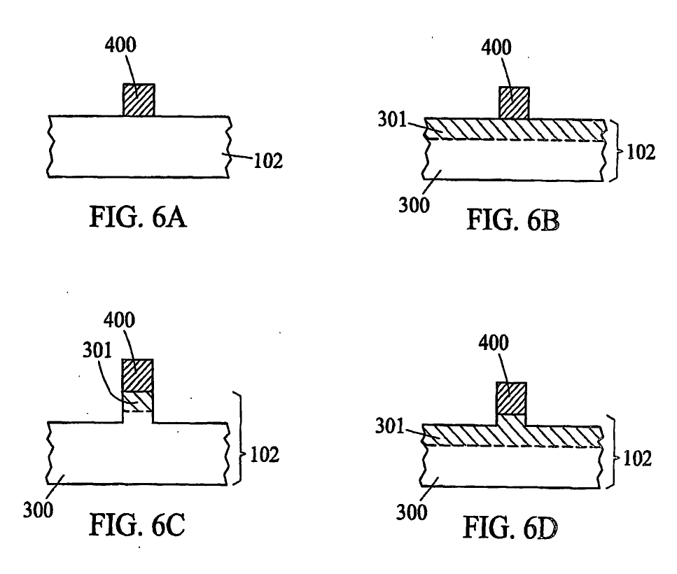

FIGS. 6A-6D illustrate positive nanometer-pitched features formed on compound and non-compound semiconductor substrates according to an embodiment of the present invention. Referring to FIG. 6A, nanometer-pitched feature 400 may be formed on substrate 102 using the edge definition lithography steps described above. In FIG. 6A, substrate 102 is assumed to be a non-compound semiconductor material, such as silicon or gallium arsenide.

Referring to FIG. 6B, nanometer-pitched feature 400 is formed on substrate 102 using the edge definition lithography steps described above. In FIG. 6B, substrate 102 comprises a two layers of different semiconductor materials.

FIG. 6C illustrates a nanoscale feature formed by etching layers 300 and 301 of substrate 102. In FIG. 6D, the nanoscale feature is formed only by etching layer 301.

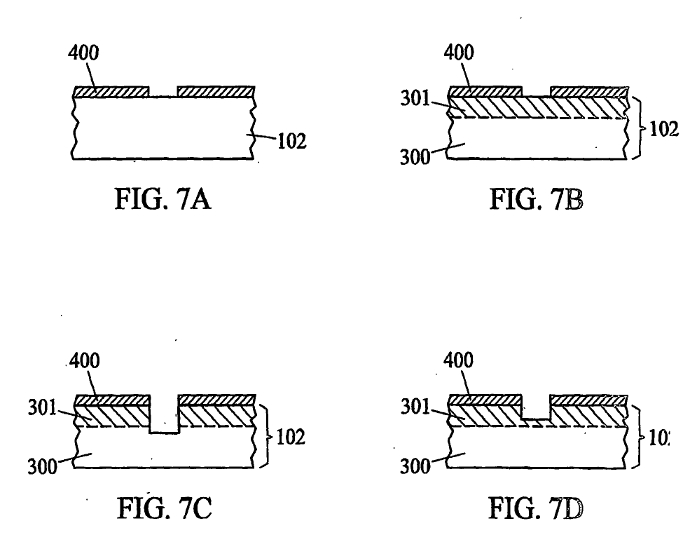

FIGS. 7A-7D illustrate negative nanoscale features formed on compound and non-compound semiconductor substrates using edge definition lithography according to an embodiment of the present invention. Referring to FIG. 7A, nanometer pitched channel 402 is formed in masking material 108 using the steps described above with regard to FIGS. 4A-4E. In FIG. 7A, substrate 102 is assumed to be a non-compound semiconductor material, such as silicon or gallium arsenide.

In FIG. 7B, nanoscale channel 402 is defined in material 108 using the steps described above with regard to FIGS. 4A-4E. In FIG. 7B, semiconductor material is a compound semiconductor material, including layers 300 and 301 as described above with regard to FIG. 6B. FIG. 7C illustrates an extension of the process illustrated in FIG. 7C where a nanometer-pitched channel is etched into layers 300 and 301. FIG. 7D illustrates an alternate process where the etching extends only into layer 301.

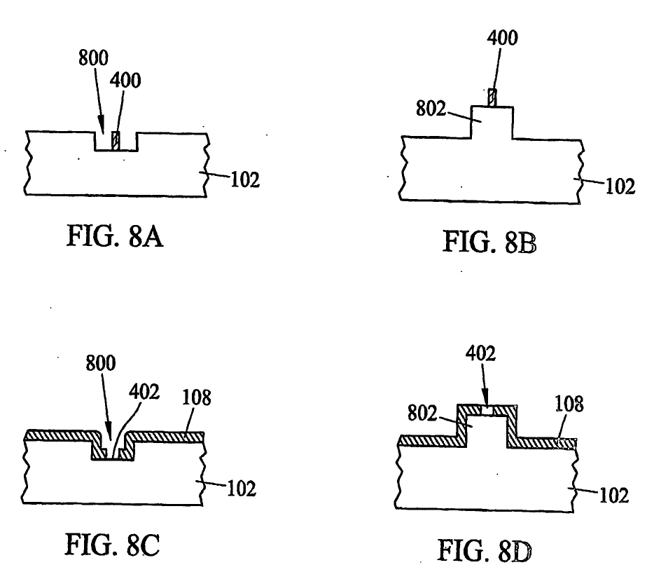

The edge definition processes described herein may be used to form semiconductor materials on micro-scale features, such as mesas and channels or holes. FIG. 8A illustrates formation of a nanometer-pitched sidewall 400 in a nanometer-scale hole 800. FIG. 8B illustrates the formation of nanometer-scale sidewall 400 on micrometer-scale mesa 802. In both FIGS. 8A and 8B, sidewall 400 may be performed using edge definition lithography, as described above.

FIG. 8C illustrates the formation of negative edge defined features holes or channels 800 and mesas 802. In FIG. 8C, channel 402 is etched in material 108 using the steps described above with respect to FIG. 4. Channel 402 is located in microscale hole 800. In FIG. 8C, channel 402 is formed in material 108 and located on top of microscale mesa 802.

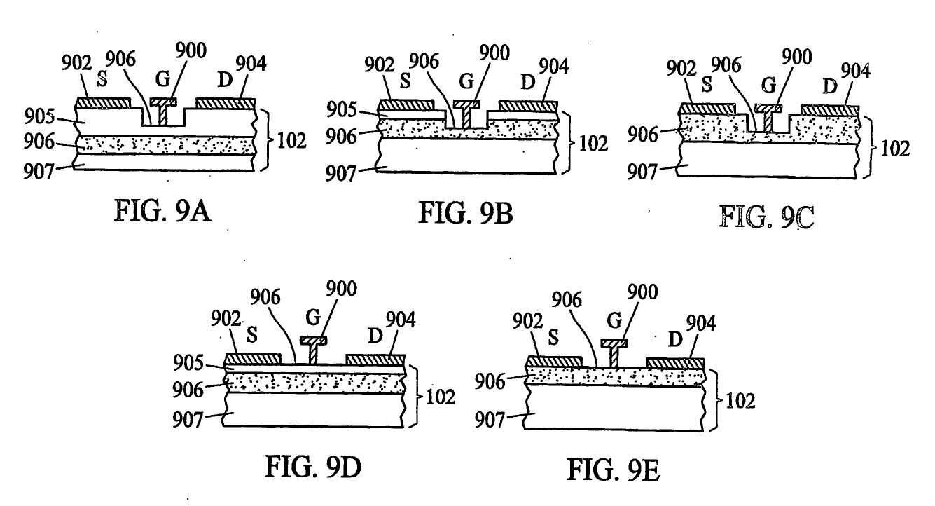

As described above, the edge definition lithography techniques described herein may be used to form nanometer scale HFETs or MESFETs. FIG. 9A illustrates an edged defined HFET according to an embodiment of the present invention. Referring to FIG. 9A, the HFET includes an edge-defined gate 900 formed using the edge definition lithography steps discussed above with regard to FIGS. 4 and 5. The MESFET also includes a source contact 902 and a drain contact 904 located on a corresponding donor/contact layer 905 formed using conventional lithographic techniques. In addition to donor/contact layer 905, substrate 102 may also include a channel layer 906, and a buffer layer 907. Layers 905-907 may respectively be formed of AlGaN, InGaN, and GaN or another combination of elemental semiconductor or compound semiconductor materials, such as those used for layers 301 and 302 described above. Source and drain contacts 902 and 904 may be formed of metallic materials with ohmic properties to provide a low-resisance electrical connection to the underlying semiconductor materials. Gate 905 may also be a metal with rectifying properties in conjunction with the underlying semiconductor.

The channel in which gate 900 is located may be etched into the donor/semiconductor contact layer only or in the donor/semiconductor contact and channel layers of substrate 102. In FIG. 9A, channel 906 in which gate 900 is located is etched only in donor/semiconductor contact layer 908. In FIG. 9B, channel 908 is etched in both layers 906 and 907. In FIG. 9E, channel 906 is omitted, and nanometer-pitched gate 900 is formed on top of donor/semiconductor contact layer 906. In FIG. 9E, donor/semiconductor contact layer 905 is omitted, and nanometer-pitched gate 900 is formed on top of channel layer 906.

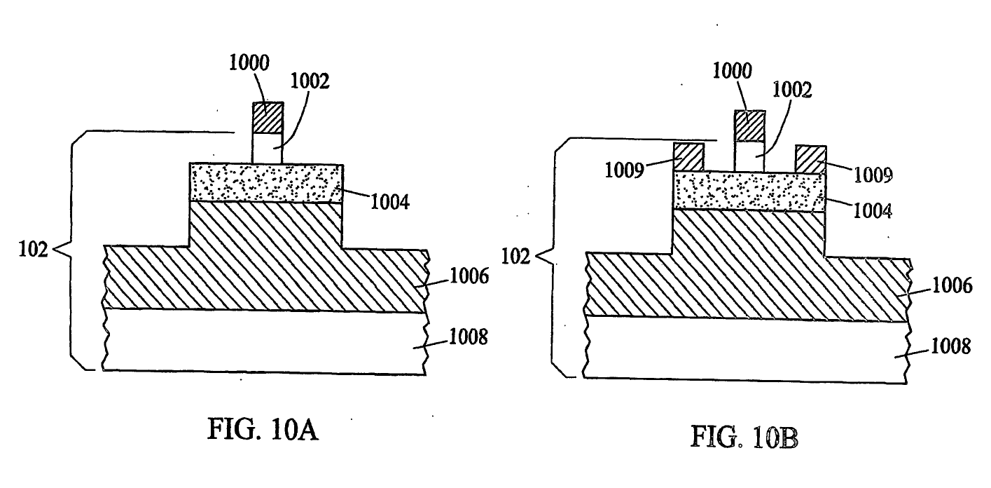

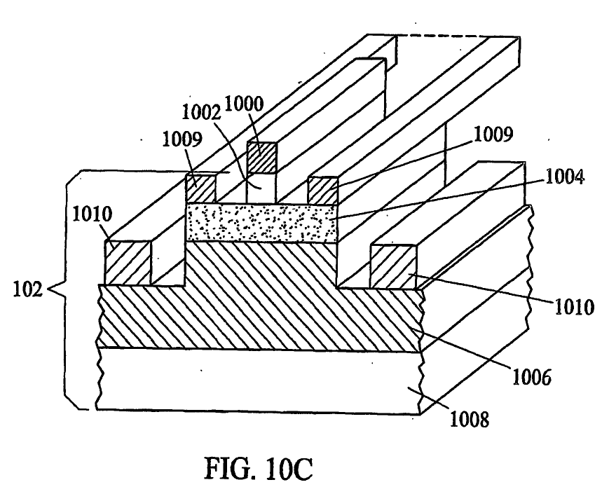

As described above, the edge definition lithography processes described herein may also be used to form nanoscale heterojunction BJTs. FIGS. 10-10C illustrate the formation of a nanoscale HBT using edge definition lithography. Referring to FIG. 10A, a nanoscale emitter contact 1000 and a nanoscale emitter 1002 may be formed using edge definition lithography, as described above. Substrate 102 may include a base layer 1004 a collector layer 1006, and a buffer layer 1008. In one example, emitter 1002 may be an N-type semiconductor material, such as N-type AlGaAs, base layer 1004 may be a P-type semiconductor material, such as P-type GaAs, collector layer 1006 may be an N-type material, such as N-type GaAs, and buffer layer 1008 may be an undoped material, such as GaAs.

In FIG. 10B, edge portions of base 1004 have been etched away to form a micrometer-scale base feature. In addition, base electrodes 1009 have been formed on opposing sides of emitter 1002 using conventional lithographic techniques. The dashed line illustrated in FIG. 10 indicates that base electrodes 1009 may be connected to each other. In FIG. 10C, portions of collector layer 1006 have been etched away and collector contacts 1010 have been deposited on opposing sides of the mesa formed in collector layer 1006 using conventional lithographic techniques. Thus, using the steps illustrated in FIGS. 10A-10C, an HBT with a nanometer scale emitter feature can be defined using edge definition lithography.

Because the methods and systems described herein allow formation of multi-periodic arrays of nano-scale features, the methods and systems described herein are suitable for formation of nanoscale devices. In addition, because the formation of multi-periodic nano-scale features can be performed using conventional photolithography, the cost of producing such features is reduced, and the throughput of the processes for producing such features is increased over specialized nanoscale lithographic techniques, such as electron beam lithography.

It will be understood that various details of the invention may be changed without departing from the scope of the invention. Furthermore, the foregoing description is for the purpose of illustration only, and not for the purpose of limitation, as the invention is defined by the claims as set forth hereinafter.

What is claimed is:

1. A method for forming a plurality of channels in or on a substrate, the method comprising:
(a) depositing a first masking material on a substrate having a first region at a first level and a second region at a second level higher than the first level;
(b) etching the first masking material from the substrate to produce a first sidewall extending from the substrate at an intersection of the first and second regions;
(c) depositing, on the substrate, a second masking material different from the first mask material, the second masking material covering the first and second regions and the first sidewall;
(d) etching the second masking material from the substrate to produce a second sidewall adjacent to the first sidewall, the first and second sidewalls having pitches on the order of nanometers;
(e) repeating steps (a)-(d) a predetermined number of times to produce a plurality of adjacent nanometer-pitched sidewalls alternatingly formed of the first and second masking materials, the adjacent nanometer-pitched sidewalls forming a plurality of nanometer-pitched channels on the substrate.

2. The method of claim 1 comprising selectively etching one of the first and second masking materials from the substrate, leaving sidewalls formed of the masking material remaining on the substrate, the sidewalls being spaced from each other on the substrate by nanometer-scale dimensions and etching regions of the substrate between the sidewalls to form a plurality of first channels in the substrate spaced from each other by nanometer-scale dimensions.

3. The method of claim 2 wherein the substrate includes sidewalls between the channels having nanometer-scale dimensions.

4. The method of claim 1 wherein depositing a first masking material on a substrate includes depositing the first masking material on the substrate with the first degree of anisotropy and wherein etching the first masking material from the substrate includes etching the first masking material from the substrate with a second degree of anisotropy being different from the first degree of anisotropy.

5. The method of claim 4 wherein depositing and etching the first masking material from the substrate with different degrees of anisotropy includes depositing the first masking material with a greater thickness in the vertical direction at the intersection of the first and second regions of the substrate than the thickness of the first masking material in the first and second regions and uniformly etching the first masking material from the substrate in the vertical direction, thereby producing the first sidewall.

6. The method of claim 1 wherein etching the first and second masking material from the substrate includes etching the first and second masking materials using a chemical or mechanical process.

7. The method of claim 1 wherein depositing a second masking material on the substrate includes depositing the second masking material on the substrate with a first degree of anisotropy and wherein etching the second masking material from the substrate includes etching the second masking material from the substrate with a second degree of anisotropy being different from the first degree of anisotropy.

8. The method of claim 7 wherein depositing and etching the second masking material from the substrate with different degrees of anisotropy includes depositing the second masking material with a greater thickness in the vertical direction in an area adjacent to the first sidewall than the thickness of the second masking material in the first and second regions and uniformly etching the second masking material from the substrate in the vertical direction, thereby producing the second sidewall.

9. The method of claim 1 wherein selectively etching one of the first and second mask materials from the substrate includes performing the etching using a chemical or mechanical process.

10. The method of claim 2 wherein spacing between the first channels is uniform.

11. The method of claim 2 wherein spacing between the first channels is non-uniform.

12. The method of claim 2 wherein forming a plurality of first channels in the substrate includes forming a plurality of structures in substrate separated by the first channels wherein the structures are spaced from each other by nanometer-scale dimensions and being of uniform thickness.

13. The method of claim 2 wherein forming a plurality of first channels in the substrate includes forming a plurality of structures in substrate separated by the first channels wherein the structures are spaced from each other by nanometer-scale dimensions and being of non-uniform thickness.

14. The method of claim 1 wherein the first and second sidewalls and the channels are spaced from each other by decananometer-scale dimensions.

15. A system including a plurality of multi-periodic, nanometer-scale semiconductor devices formed using the method of claim 1.

16. A plurality of multi-periodic, nanometer-scale electromechanical devices formed using the method of claim 1.

17. A method for forming a channel of nanometer-scale dimensions in a substrate, the method comprising:
(a) forming a first sidewall of first masking material on a substrate, the first sidewall having nanometer-scale width;
(b) depositing a second masking material on the substrate, such that the second masking material covers the first sidewall with a first thickness, forms second and third sidewalls on first and second sides of the first sidewall with a second thickness being less than the first thickness, and covers the substrate in regions adjacent to the second and third sidewalls with the first thickness;
(c) etching portions of the second and third sidewalls from the substrate such that the first and second sides of the first sidewall form discontinuities in the second masking material;
(d) removing the first sidewall from the substrate leaving a channel in the second masking material having substantially the same width as the first sidewall; and
(e) etching a channel in the substrate corresponding to the channel in the second masking material.

18. The method of claim 17 wherein forming a first sidewall of first masking material of nanometer-scale width on a substrate includes forming the first sidewall using edge definition lithography.

19. The method of claim 17 wherein etching portions of the second and third sidewalls from the substrate includes leaving deposits of the second masking material on the substrate having substantially uniform thickness in areas where the second and third sidewalls were present.

20. The method of claim 17 wherein etching portions of the second and third sidewalls from the substrate includes performing the etching using a chemical or mechanical process.

21. The method of claim 17 wherein removing the first sidewall from the substrate includes removing the first sidewall using a lift off method.

22. The method of claim 17 comprising forming a fourth sidewall of nanometer-scale dimensions in the channel.

23. The method of claim 22 comprising forming fifth and sixth sidewalls of nanometer-scale dimensions on opposite sides of the fourth sidewall to form a mushroom-shaped structure.

24. The method of claim 23 wherein the mushroom-shaped structure comprises a gate material for a semiconductor device.

25. A semiconductor device formed using the method of claim 24.

26. A semiconductor device formed using the method of claim 17.

27. The method of claim 1 wherein the substrate comprises a compound semiconductor material.

28. The method of claim 27 wherein the compound semiconductor material includes one of GaN, AlGaN, and InGaN.

29. The method of claim 1 wherein the substrate comprises a semiconductor heterostructure containing one of Si, GaAs, InGaAs, AlGaAs, SiGe, SiC, GaN, AlGaN, and InGaN.

30. The method of claim 1 wherein performing steps (a)-(e) includes forming the plurality of first channels in a first direction in the substrate and wherein the method further comprises repeating steps (a)-(e) to form a plurality of second channels in the substrate, the second channels intersecting the first channels at an oblique angle.

31. The system of claim 15 wherein the multi-periodic, nanometer scale devices include one of: a heterostructure field effect transistor (FET), a heterojunction bipolar junction transistor (BJT), a gallium-nitride-based FET, an indium-gallium-arsenide-based FET, a gallium arsenide FET, an indium-gallium-arsenide-based FET, and a gallium phosphide FET.

32. The method of claim 17 wherein the substrate comprises a compound semiconductor material.

33. The method of claim 32 wherein the compound semiconductor material includes one of GaN, AlGaN, and InGaN.

34. A semiconductor structure having an edge-defined, nanometer-pitched feature, the semiconductor structure comprising:
(a) a substrate comprising a first layer including a first semiconductor material and a second layer including a second semiconductor material, the first semiconductor material being different from the second semiconductor material; and
(b) at least one nanometer-pitched feature being located on the substrate, the nanometer-pitched feature being formed using edge definition lithography.

35. The semiconductor structure of claim 34 wherein the nanometer-pitched feature comprises a nanometer-pitched wall located on the first layer.

36. The semiconductor device of claim 35 wherein the nanometer-pitched wall is formed by a portion of at least one of the first and second layers.

37. The semiconductor structure of claim 34 wherein the nanometer-pitched feature comprises a nanometer-pitched channel formed in a masking material deposited on the substrate.

38. The semiconductor structure of claim 37 wherein the channel extends into at least one of the first and second layers.

39. A semiconductor structure including at least one micrometer-scale feature and at least one nanometer-scale feature being defined using edge definition lithography, the semiconductor structure comprising:
(a) a semiconductor substrate;
(b) at least one micrometer-scale feature being located in or on the semiconductor substrate; and
(c) at least one nanometer-scale feature being located in or on the micrometer-scale feature, the nanometer-scale feature being defined using edge definition lithography.

40. The semiconductor structure of claim 39 wherein the micrometer-scale feature comprises a channel or hole being defined by the substrate and the nanometer-pitched feature comprises a sidewall.

41. The semiconductor structure of claim 39 wherein the micrometer-scale feature comprises a mesa and the nanometer-scale feature comprises a sidewall located on top of the mesa.

42. The semiconductor structure of claim 39 wherein the micrometer-scale feature comprises a channel or hole being defined by the substrate and wherein the nanometer-scale feature comprises a channel located in a masking material deposited in the hole.

43. The semiconductor structure of claim 39 wherein the micrometer-scale feature comprises a mesa located on the substrate and wherein the nanometer-scale feature comprises a channel located in a masking material deposited on the mesa.

44. A field effect transistor having an edge-defined gate, the field effect transistor comprising:
(a) a substrate including a buffer layer of a first semiconductor material and a channel layer of a second semiconductor material, the second semiconductor material being different from the first semiconductor material; and
(b) a gate electrode being located on the substrate between the source and drain electrodes, the gate electrode being formed using edge definition lithography.

45. The field effect transistor of claim 44 wherein the substrate comprises a donor layer comprising a third semiconductor material being different from the first and second semiconductor materials, the donor layer including a channel, wherein the gate electrode is located in the channel.

46. The field effect transistor of claim 45 wherein the channel extends into the channel layer.

47. The field effect transistor of claim 44 wherein the channel layer includes a channel and the gate electrode is located in the channel.

48. The field effect transistor of claim 44 wherein the substrate includes a donor layer adjacent to the channel layer and the gate electrode is located on the donor layer.

49. The field effect transistor of claim 44 wherein the gate electrode is located on the channel layer.

50. A bipolar junction transistor having a nanometer-scaled edge-defined feature, the bipolar junction transistor comprising:
(a) a collector layer;
(b) a base layer being adjacent to the collector layer; and
(c) a nanometer-scale emitter being defined on the base layer using edge definition lithography.
